(19) United States
(12) Patent Application Publication
(10) Pub. No.: US 2015/0305458 A1
(43) Pub. Date: Oct. 29, 2015

(54) HOUSING AND PORTABLE DEVICE USING THE SAME

(71) Applicant: Hon Hai Precision Industry Co., Ltd., New Taipei (TW)

(72) Inventor: SHAO-HAN CHANG, New Taipei (TW)

(21) Appl. No.: 14/525,844

(22) Filed: Oct. 28, 2014

(30) Foreign Application Priority Data
Apr. 28, 2014 (CN) 201410173522.1

(51) Int. Cl. A45C 11/00; A45C 11/38; H05K 5/02; H05K 5/03; G06F 1/16; H05K 5/00

(52) U.S. Cl. CPC A45C 11/00; G06F 1/1626; G06F 1/1656; H05K 5/0004; H05K 5/0217; H05K 5/03; A45C 11/38; A45C 2011/002

(57) ABSTRACT

A portable device having a housing includes a plastic portion, a metal element integrated with the plastic portion. The metal element includes a support portion, a closed sidewall substantially perpendicular to the support portion, four first bent portions, and four connecting portions configured to connect the closed sidewall to each first bent portion. The closed sidewall can extend from an outside periphery of the support portion to a first direction, and the first bent portions can extend to a second direction substantially contrary to the first direction. The connecting portions are embedded inside the plastic portion and substantially perpendicular to the closed sidewall and the first bent portion.

### FIELD

The subject matter herein generally relates to an electrical apparatus, and particularly to a portable device having high mechanical strength and lightweight.

### BACKGROUND

Electronic devices such as mobile phones, personal digital assistants (PDA), or cameras need have high mechanical strength, and to be convenient for outdoor use, the electronic device must be light weight and have a thin profile.

### BRIEF DESCRIPTION OF THE DRAWINGS

Implementations of the present technology will now be described, by way of example only, with reference to the attached figures.

FIG. 1 is an exploded, isometric view of a portable device according to an embodiment of the present disclosure.

FIG. 2 is a top view of a housing of the portable device shown in FIG. 1.

FIG. 3 is an isometric view of a metal element of the housing shown in FIG. 2.

FIG. 4 is an abbreviated, cross-sectional view of the housing shown in FIG. 2 taken along line IV-IV.

FIG. 5 is an abbreviated, cross-sectional view of the housing shown in FIG. 2 taken along line V-V.

FIG. 6 is a top view of the portable device as assembled shown in FIG. 1.

FIG. 7 is an abbreviated, cross-sectional view of the portable device shown in FIG. 6 taken along line VII-VII.

FIG. 8 is an abbreviated, cross-sectional view of a portable device according to another embodiment of the present disclosure.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. Also, the description is not to be considered as limiting the scope of the embodiments described herein. The drawings are not necessarily to scale and the proportions of certain parts have been exaggerated to better illustrate details and features of the present disclosure.

Several definitions that apply throughout this disclosure will now be presented.

The term “coupled” is defined as connected, whether directly or indirectly through intervening components, and is not necessarily limited to physical connections. The connection can be such that the objects are permanently connected or releasably connected. The term “outside” refers to a region that is beyond the outermost confines of a physical object. The term “inside” indicates that at least a portion of a region is partially contained within a boundary formed by the object. The term “substantially” is defined to be essentially conforming to the particular dimension, shape or other word that substantially modifies, such that the component need not be exact. For example, substantially cylindrical means that the object resembles a cylinder, but can have one or more deviations from a true cylinder. The term “comprising”, when utilized, means “including, but not necessarily limited to”; it specifically indicates open-ended inclusion or membership in the so-described combination, group, series and the like.

The present disclosure is described in relation to a housing and a portable device.

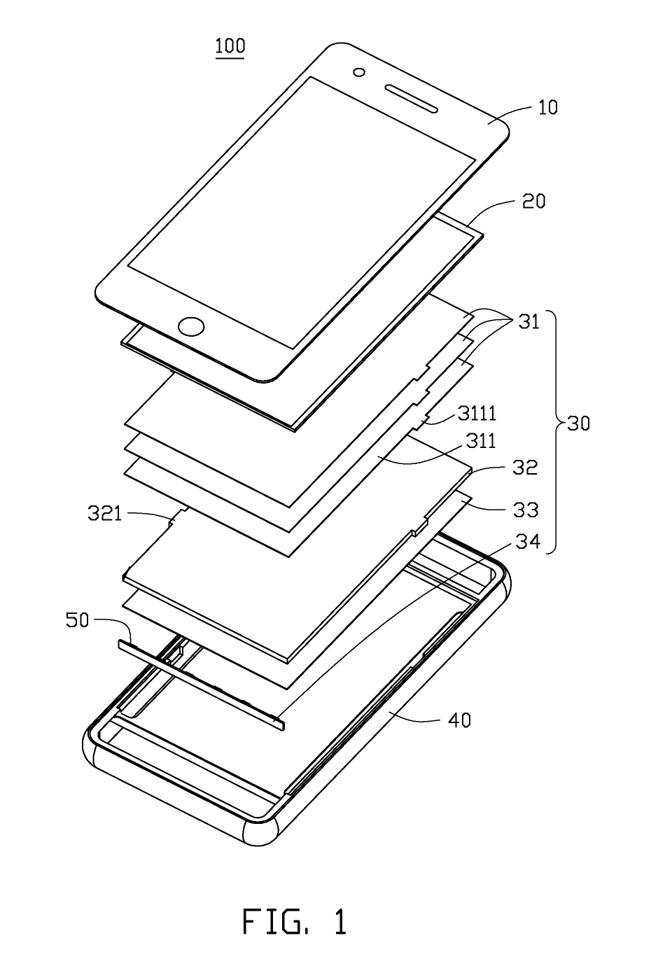

FIG. 1 illustrates that a portable device 100 can include a protection panel 10, a display panel 20, a backlight module 30, and a housing 40, stacked in order. The display module 20 can be positioned facing the protection panel 10. The housing 40 can couple to the protection panel 10. The display panel 20 and backlight module 30 can be sandwiched between the protection panel 10 and housing 40. The housing 40 and protection panel 10 can cooperatively form a receiving space to sandwich the display panel 20 and backlight module 30.

A size and shape of the protection panel 10 can match that of the display panel 20. The protection panel 10 can be used for looking inside the portable device 100, and protecting the display panel 20 below the protection panel 10. In at least one embodiment, the display panel 20 can be a crystal display panel.

The backlight module 30 can include an optical film 31, a light guiding plate 32, a reflective sheet 33, and a lamp plate 34 stacked in order. The optical film 31 can include a plurality of diffusion sheets 311 alternatively stacked. The diffusion sheet 311 can include two first protrusion portions 3111, positioned on either opposite side of the diffusion sheet 311. The first protrusion portion 3111 can protrude away from each side of the diffusion sheet 311. The first protrusion portion 3111 can be parallel with a surface of the diffusion sheet 311 facing the light guiding plate 32. The first protrusion portions 3111 of each diffusion sheet 311 positioned on the same side can face each other.

The light guiding plate 32 can be sandwiched between the optical sheet 31 and the reflective sheet 33, and can include two second protrusion portions 321 respectively facing the two first protrusion portions 3111 of the each optical sheet 31. The shape and size of the second protrusion portions 321 can match that of the first protrusion portions 3111. In at least one embodiment, the first protrusion portions 3111 can be symmetrically positioned on opposite sides lengthwise along the diffusion sheets 311, and the second protrusion portions 321 can be symmetrically positioned on opposite sides lengthwise along the light guiding plate 32.

The portable device 100 can further include a plurality of light sources 50 configured to supply light to the display panel 20. In at least one embodiment, the light source 50 is an LED. The lamp plate 34 can be a strip configured to install the light sources 50. The lamp plate 34 can be positioned widthwise across the optical film 31, the light guiding plate 32, and the reflective sheet 33.

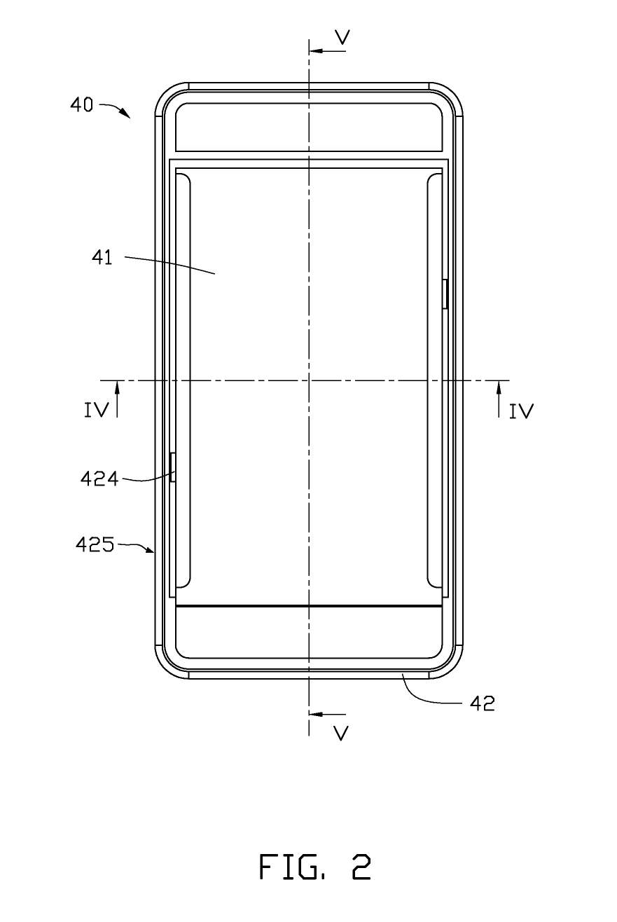

FIG. 2 illustrates that the housing 40 can include a metal element 41 and a plastic portion 42 integrated with the metal element 41. The metal element 41 can be at least partially integrally formed with the plastic portion 42 by insert molding method, whereby the housing 40 can have a thin profile, light weight and reserved mechanical properties compared with a traditional housing having a metal frame functioning as a middle frame coupled to another housing body.

The plastic portion 42 can further define two rectangle latching portions 424 defined inside the plastic portion 42. The two latching portions 424 can be located on either opposite side of the plastic portion 42 along a long side direction and unsymmetrical with each other. The section of the latching portions 424 can be respectively facing the first protrusion portions 3111 and the second protrusion portions 321 (shown in FIG. 1). Therefore, the diffusion sheets 311 can be secured in the plastic portion 42 by the latching portions 424, to restrict the moving of diffusion sheets 311, so that the structure stability of portable device 100 can be enhanced. In other embodiments, more than two latching portions can be included. In one embodiment, the plastic portion 42 can be substantially rectangular and can include a continuous side wall 425. The two rectangle latching portions 424 can be positioned on opposite sides of the continuous side wall 425.

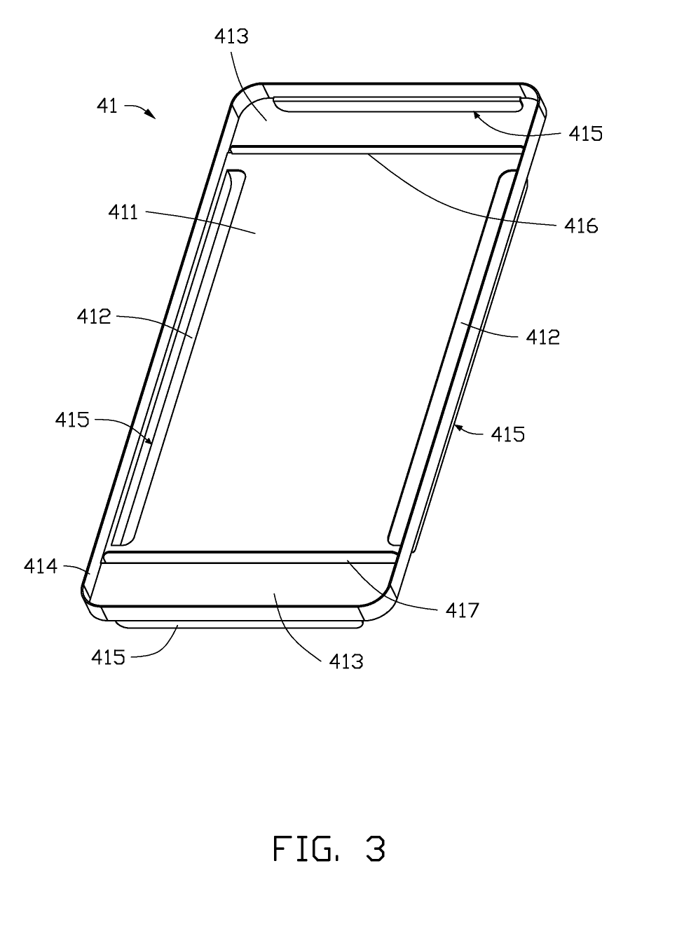

FIG. 3 illustrates that the metal element 41 can include a support portion 411 and an closed sidewall 414 positioned outside the support portion 411. The closed sidewall 414 can be hollow and substantially rectangular. The closed sidewall 414 can be substantially perpendicular to the support portion 411. The support portion 411 can be substantially I-shaped and connected to opposite sides of the closed sidewall 414.

The metal element 41 can further include two pairs of hollow portions including a pair of first hollow portions 412 and a pair of second hollow portions 413. The first hollow portions 412 and second hollow portions 413 can be strip-shaped. The first hollow portions 412 and second hollow portions 413 can be positioned adjacent to an outside periphery of the support portion 411 and located between the support portion 411 and the closed sidewall 414.

In at least one embodiment, the first hollow portions 412 can be positioned lengthwise on opposite sides of the support portion 411, and the second hollow portions 413 can be positioned widthwise on opposite sides of the support portion 411. The two first hollow portions 412 can be parallel with each other and distanced from each other. The two second hollow portions 413 can be parallel with each other and distanced from each other.

The closed sidewall 414 can be continuous and enclose the support portion 411, the two pairs of hollow portions including first hollow portions 412 and second hollow portions 413, and adjacent to the outside periphery of the support portion 411 and the hollow portions 412 and 413. The closed sidewall 414 can extend from the outside periphery of the support portion 411 to a first direction. The first direction can be substantially perpendicular to the support portion 411. The closed sidewall 414, the support portion 411, and the hollow portions 412 can cooperatively form a box-shaped structure.

The metal element 41 can further include four first bent portions 415 connected to the closed sidewall 414, a second bent portion 416, and a third bent portion 417 facing the second bent portion 416. The first bent portion 415 can be connected to the closed sidewall 414, and extend to a second direction substantially contrary to the first direction. The second bent portion 416 and third bent portion 417 can be distanced from each other and positioned on either opposite end portion of the support portion 411, and parallel with each other. The second bent portion 416 and third bent portion 417 can substantially extend to the same direction as the closed sidewall 414. The second bent portion 416 and third bent portion 417 can be adjacent to each opposite side of the second hollow portion 413 away from the first bent portion 415, and each second hollow portion 413 can be located between the first bent portion 415 and the second bent portion 416. In one embodiment, the four first bent portions 415 can a front one, a rear one substantially opposite to and parallel with the front one, a left-side one, and a right-side one substantially opposite to and parallel with the left-side one. The left-side one and the right-side one can be substantially perpendicular to the front one and the rear one.

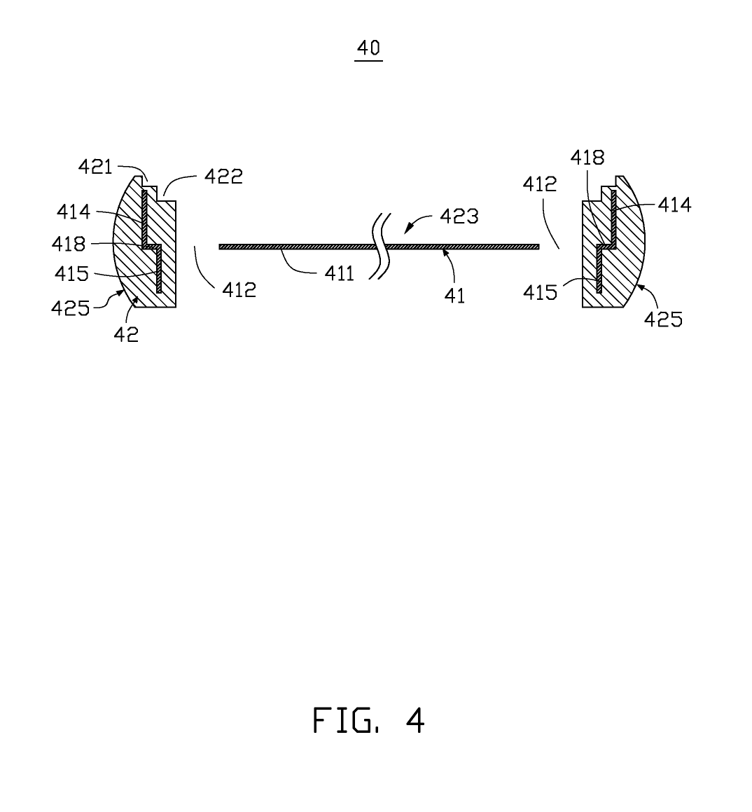

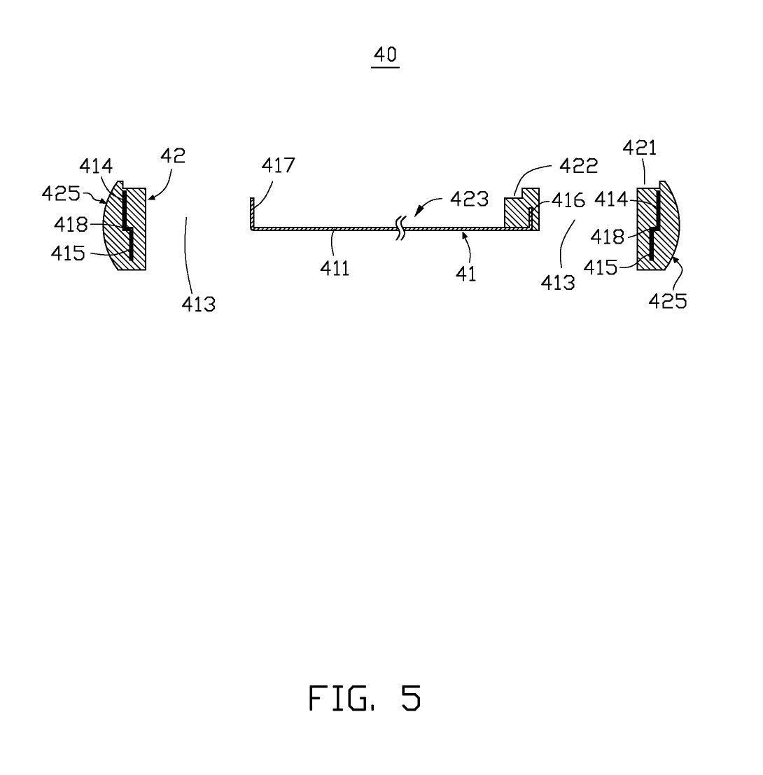

FIGS. 4 and 5 illustrate two cross-sectional views of FIG. 3 respectively taken along lines IV-IV and V-V, and illustrate that the metal element 40 can further include two pairs of connecting portions 418, configured to connect the closed sidewall 414 to the four first bent portions 415. The connecting portion 418 can be substantially perpendicular to the closed sidewall 414 and the first bent portion 415. The two first bent portions 415 along the long side direction of the support portion 411 can be located between the first hollow portion 412 and the connecting portion 418. The two first bent portions 415 along the width direction of the support portion 411 can be located between the second hollow portion 413 and the connecting portion 418.

In one embodiment, the two pairs of connecting portions 418 can include a front one, a rear one substantially opposite to and parallel with the front one, a left-side one, and a right-side one substantially opposite to and parallel with the left-side one. The front connecting portion 418 can connect the closed sidewall 414 to the front first bent portions 415, and the rear connecting portion 418 can connect the closed sidewall 414 to the rear first bent portions 415. The left-side connecting portion 418 can connect the closed sidewall 414 to the left-side first bent portions 415, and the right-side connecting portion 418 can connect the closed sidewall 414 to the right-side first bent portions 415.

One of the pair of first hollow portions 412 can be defined in the support portion 411 substantially along the left-side first bent portion 415, and another one of the pair of first hollow portions 412 can be defined in the support portion 411 substantially along the right-side first bent portion 415. One of the pair of second hollow portions 413 can be defined in the support portion 411 substantially along the rear first bent portion 415, and another one of the pair of second hollow portions 413 can be defined in the support portion 411 substantially along the front first bent portion 415.

The closed sidewall 414, the first bent portions 415, and the connecting portion 418 can be substantially embedded inside the plastic portion 42. In one embodiment, the closed sidewall 414, the first bent portions 415, and the connecting portion 418 can be embedded inside the continuous side wall 425. The closed sidewall 414, the first bent portions 415 can be substantially parallel with the continuous side wall 425, and the connecting portion 418 can be substantially perpendicular to the continuous side wall 425. The closed sidewall 414 embedded inside the plastic portion 42 can be configured to enhance the mechanical properties of the plastic portion 42 along the first direction. The first bent portion 415 embedded inside the plastic portion 42 can be configured to enhance the mechanical properties of the plastic portion 42 along the second direction. As the first direction can be substantially perpendicular to the support portion 411 and the second direction can substantially be contrary to the first direction, the closed sidewall 414, the first bent portion 415 can cooperatively enhance the mechanical properties along the periphery of the housing 40. The continuous side wall 425 of the plastic portion 42 can thus have reserved mechanical properties to enhance the housing 40.

The second bent portion 416 and third bent portion 417 can be configured to enhance the deformation properties of the housing 40 and the supporting strength of the support portion 411.

In at least one embodiment, the second bent portion 416 can be embedded inside the plastic portion 42. The second bent portion 416 can be embedded inside an inner portion of the plastic portion 42. The inner portion can be positioned inside, connected to the continuous side wall 425 and can be substantially perpendicular to the continuous side wall 425 (shown in FIGS. 2 and 5). The third bent portion 417 and support portion 411 away from the second bent portion 416 can be exposed outside the plastic portion 42. At the same time, the third bent portion 417 can be configured to install the lamp plate 34 having the light sources 50 (shown in FIG. 1), whereby the heat generated in the lamp plate 34 (shown in FIG. 1) can be efficiently diffused outside by the conductive metal support portion 411 adjacent to the third bent portion 417. Therefore, the temperature generated in the housing 40 can be reduced and the lighting efficiency of light sources 50 installed on the lamp plate 34 can be improved, avoiding the heat damage of the light sources 50.

In other embodiments, the second bent portion 416 and support portion 411 away from the third bent portion 417 can be exposed outside the plastic portion 42. At the same time, the third bent portion 417 can be embedded inside the plastic portion 42, and the second bent portion 416 exposed outside the plastic portion 42 can be configured to install the lamp plate 34 (shown in FIG. 1). The third bent portion 417 can be embedded inside the inner portion of the plastic portion 42 positioned inside, connected to the continuous side wall 425 (shown in FIGS. 2 and 5).

The plastic portion 42 can include a first receiving portion 421, a second receiving portion 422 adjacent to the first receiving portion 421, and a third receiving portion 423. The first receiving portion 421, the second receiving portion 422, and the third receiving portion 423 can be arranged in steps.

The first receiving portion 421 can be continuous and positioned in accordance to the connecting portion 418 and the closed sidewall 414. The shape and size can match that of the protection panel 10 (shown in FIG. 1), configured to receive the protection panel 10 (shown in FIG. 1). The second receiving portion 422 can be smaller than the first receiving portion 421, and connected to the first receiving portion 421. A cross-sectional view of the second receiving portion 422 can be parallel with the first receiving portion 421 and the support portion 411. The second receiving portion 422 can be configured to receive the display panel 20 (shown in FIG. 1).

The third receiving portion 423 can be located between the third bent portion 417 and the second receiving portion 422. The third receiving portion 423 can be a receiving space cooperatively formed by the support portion 411, the third bent portion 417, a section of the plastic portion 42 embedding the closed sidewall 414, and a section of the plastic portion 42 embedding the second bent portion 416. The third receiving portion 423 can be smaller than the second receiving portion 422, configured to receive the back light module 30 (shown in FIG. 1). The lamp plate 34 (shown in FIG. 1) can be received in the third receiving portion 423 and installed on the third bent portion 417. In other embodiments, one or more than two receiving portions can be included.

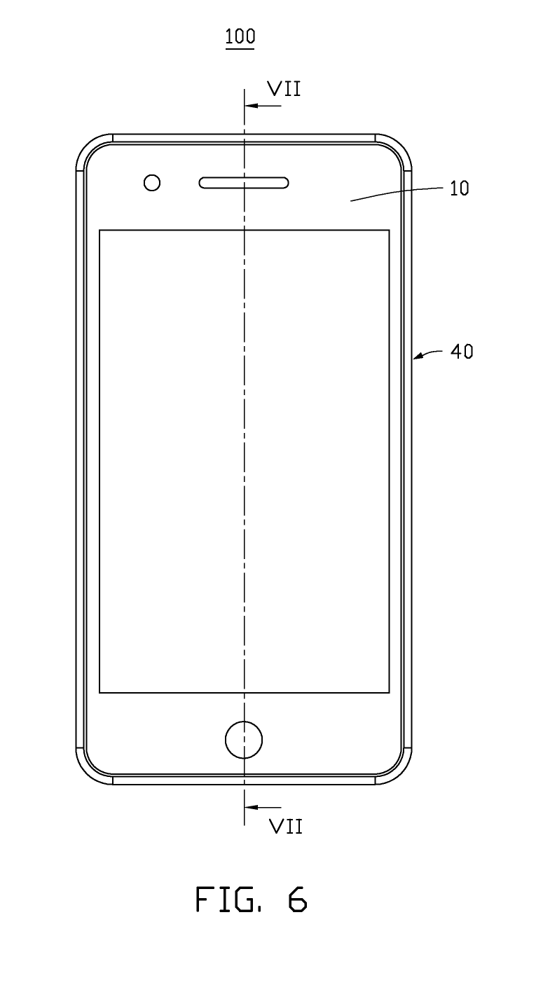

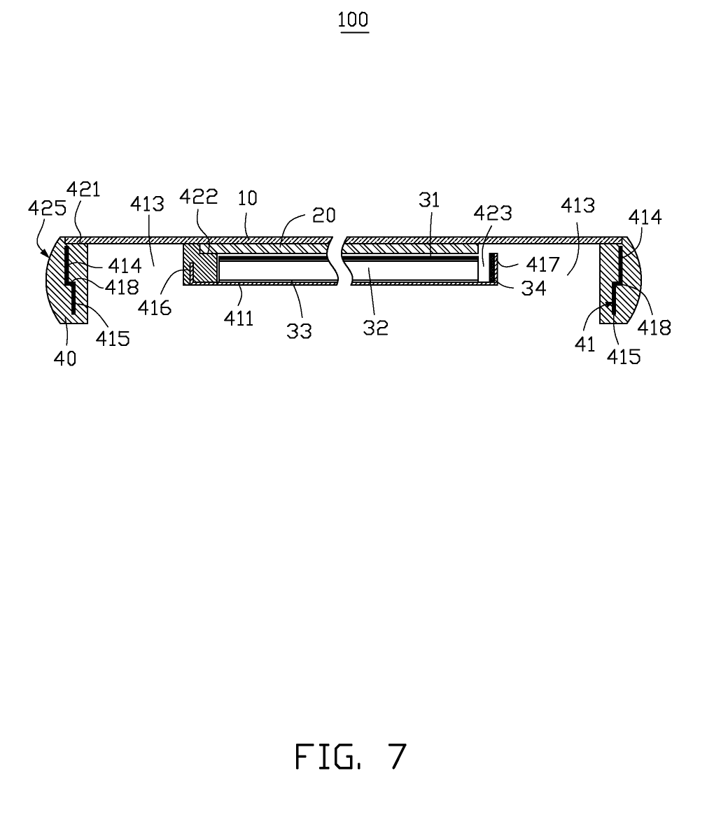

FIG. 6 illustrates an assembly view of the portable device 100, and FIG. 7 illustrates a cross-sectional view of the portable device 100 having the housing 40. The housing 40 can be coupled to the protecting panel 10 and the protecting panel 10 can be received in the first receiving portion 421. The display panel 20 can be received in the second receiving portion 422 and positioned under the protecting panel 10. The backlight module 30 can be received between the second bent portion 416 and the third bent portion 417 and stacked between the support portion 411 and the display panel 20. The closed sidewall 414, the first bent portion 415, the connecting portion 418 configured to connect the first bent portion 415 to the closed sidewall 414 can be embedded inside the plastic portion 42. The closed sidewall 414 can extend to the first direction and the first bent portion 415 can extend to the second direction opposite to the first direction. The connecting portion 418 can be substantially parallel with the support portion 411. The pair of bent portions including the second bent portion 416 and third bent portion 417 positioned on opposite end portion of the support portion 411 can extend to the first direction substantially the same as the closed sidewall 414.

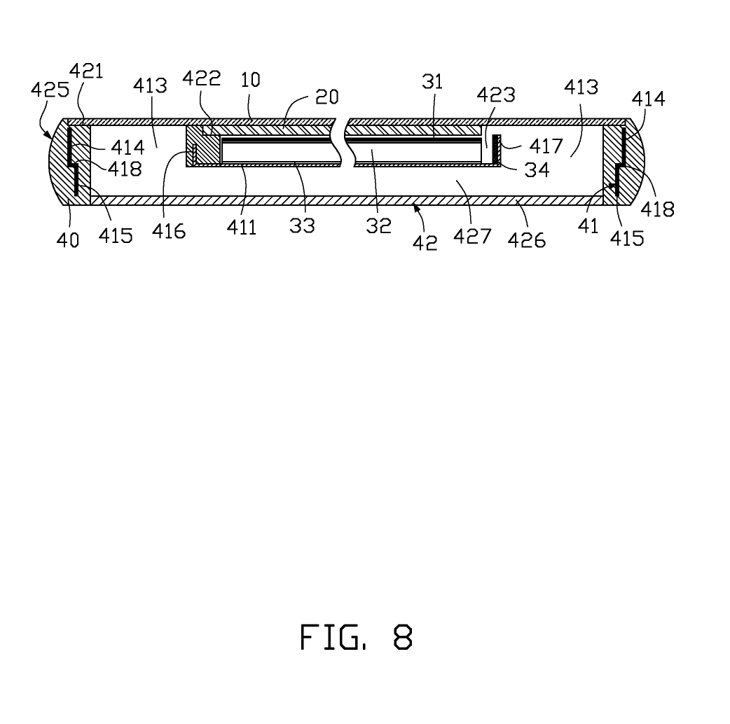

FIG. 8 illustrates that in other embodiments the plastic portion 42 can further include a support plane 426 connected to the substantially continuous side wall 425. The support plane 426 can be substantially perpendicular to the substantially continuous side wall 425. The support plane 426 and the substantially continuous side wall 425 can cooperatively form a receiving space 427. The support plane 426 can be positioned on opposite ends of the substantially rectangular plastic portion 42 and be substantially parallel with the protecting panel 10.

In assembly, the lamp plate 34 can be installed on the third bent portion 417, and the reflective sheet 33 can be attached to the support portion 411 between the second bent portion 416 and the third bent portion 417. Then, the light guiding plate 32 and the optical film 31 can be positioned above the reflective sheet 33 in order, and the first protrusion portions 3111 (shown in FIG. 1) and the second protrusion portions 321 (shown in FIG. 1) can be latched in the latching portions 424 (shown in FIG. 2). Finally, the display panel 20 can be accommodated in the second receiving portion 422, and the protection panel 10 can be accommodated in the first receiving portion 421. Thus, the protection panel 10, the display panel 20, the optical sheet 31, the light guiding plate 32, the reflective sheet 33, and the lamp plate 34 can be accommodated in the housing 40 to cooperatively form an integrated unity.

As the housing 40 can include the metal element 41 and the plastic portion 42 integrally formed with the metal element 41 by the method of insert molding, the housing 40 can have a low average density and light weight. Additionally, the metal element 41 can include the closed sidewall 414 and the first bent portion 415 connected to the closed sidewall 414 by the connecting portion 418, which can enhance the mechanical properties of the housing 40. Thus, the housing 40 and the portable device 100 having the housing 40 can have the reserved mechanical properties. Further more, the display panel 20, optical panel 31, and the light guiding plate 32 can be directly accommodated in the housing 40 to form an integrated unity. Therefore, the portable device 100 having the housing 40 does not need an extra frame holding the display module 20 or an extra metal plate fastening the backlight module 30, so that portable device 100 can have low production cost and thin profile.

The embodiments shown and described above are only examples. Many details are often found in the art such as the other features of a housing and a portable device using the same. Therefore, many such details are neither shown nor described. Even though numerous characteristics and advantages of the present technology have been set forth in the foregoing description, together with details of the structure and function of the present disclosure, the disclosure is illustrative only, and changes may be made in the detail, according in matters of shape, size and arrangement of the parts within the principles of the present disclosure up to, and including the full extent established by the broad general meaning of the terms used in the claims. It will therefore be appreciated that the embodiments described above may be modified within the scope of the claims.

What is claimed is:

1. A housing comprising:
a plastic portion;
a metal element integrated with the plastic portion, comprising:
a support portion;
an closed sidewall embedded inside the plastic portion, substantially perpendicular to the support portion and extending to a first direction;
four first bent portions embedded inside the plastic portion, extending to a second direction substantially contrary to the first direction; and
four connecting portions embedded inside the plastic portion configured to connect the closed sidewall to each first bent portion and substantially perpendicular to the closed sidewall and the first bent portions.

2. The housing as claimed in claim 1, wherein, the metal element comprises two pair of hollow portions between the support portion and closed sidewall, including:
two first hollow portions lengthwise positioned on opposite sides of the support portion adjacent to the first bent portions; and
two second hollow portions widthwise positioned on opposite sides of the support portion adjacent to the first bent portions.

3. The housing as claimed in claim 2, wherein, the first hollow portions and second hollow portions are adjacent to an outside periphery of the support portion.

4. The housing as claimed in claim 2, wherein, the metal element further comprises a pair of bent portions connected to either opposite end portion of the support portion, including a second bent portion and a third bent portion extending from the support portion to the first direction.

5. The housing as claimed in claim 4, wherein, the second bent portion and third bent portion are positioned adjacent to either opposite side of the second hollow portions away from the closed sidewall.

6. The housing as claimed in claim 4, wherein, the second bent portion and third bent portion are substantially parallel with each other, and spaced from each other.

7. The housing as claimed in claim 4, wherein, the second bent portion is embedded inside the plastic portion, and the third bent portion and support portion away from the second bent portion are exposed outside the plastic portion.

8. The housing as claimed in claim 4, wherein, the third bent portion is embedded inside the plastic portion, and the second bent portion and support portion away from the third bent portion are exposed outside the plastic portion.

9. A portable device comprising:
a protection panel;
a display panel facing the protection panel;
a backlight module;
a housing coupled to the protection panel and comprising:
a plastic portion;
a metal element integrated with the plastic portion, comprising:
a support portion;
an closed sidewall embedded inside the plastic portion, substantially perpendicular to the support portion and extending to a first direction;
four first bent portions embedded inside the plastic portion, extending to a second direction substantially contrary to the first direction; and
four connecting portions embedded inside the plastic portion configured to connect closed sidewall to each first bent portion and substantially perpendicular to the closed sidewall and the first bent portions.

10. The portable device as claimed in claim 9, wherein, the metal element comprises:
two pair of hollow portions between the support portion and closed sidewall, including:
two first hollow portions lengthwise positioned on opposite sides of the support portion adjacent to the first bent portions; and
two second hollow portions widthwise positioned on opposite sides of the support portion adjacent to the first bent portions;
wherein, the first hollow portions and second hollow portions are adjacent to an outside periphery of the support portion.

11. The portable device as claimed in claim 10, wherein, the metal element further comprises a pair of bent portions connected to either opposite end portion of the support portion, including a second bent portion and a third bent portion extending from the support portion to the first direction.

12. The portable device as claimed in claim 11, wherein, the second bent portion and third bent portion are positioned adjacent to either opposite side of the second hollow portions away from the closed sidewall.

13. The portable device as claimed in claim 11, wherein, the second bent portion and third bent portion are substantially parallel with each other, and spaced from each other.

14. The portable device as claimed in claim 11, wherein, the second bent portion is embedded inside the plastic portion, and the third bent portion and support portion away from the second bent portion are exposed outside the plastic portion.

15. The portable device as claimed in claim 11, wherein, the third bent portion is embedded inside the plastic portion, and the second bent portion and support portion away from the third bent portion are exposed outside the plastic portion.

16. The portable device as claimed in claim 13, wherein the portable device includes a plurality of light sources, and the backlight module includes a lamp plate configured to install the light sources on the third bent portion.

17. The portable device as claimed in claim 14, wherein, the portable device includes a plurality of light sources, and the backlight module includes a lamp plate configured to install the light sources on the second bent portion.

18. The portable device as claimed in claim 9, wherein, the plastic portion comprises:
a first receiving portion configured to receive the protection panel;
a second receiving portion configured to receive the display panel; and
a third receiving portion configured to receive the backlight module;
wherein, the first receiving portion, the second receiving portion, and the third receiving portion are substantially aligned in a steps.

19. A housing for a portable electronic device comprising:
a plastic portion defining a receiving space, the receiving space having a support plane and a substantially continuous side wall substantially perpendicular to the support plane; and
a metal support element at least partially integrated with the plastic portion, the metal element comprising:
a support portion positioned parallel to the support plane;
a closed sidewall extending in a first direction perpendicular from the support portion and forming part of the receiving space in the continuous side wall;
a first bent portion embedded in the plastic portion and extending in a direction opposite the first direction;
a second bent portion embedded in the plastic portion and extending in a direction opposite the first direction, the second bent portion opposite to and substantially parallel to the first bent portion;
a third bent portion embedded in the plastic portion and extending in a direction opposite to the first direction substantially perpendicular to the first and second bent portions;
a fourth bent portion embedded in the plastic portion and extending in a direction opposite the first direction, the fourth bent portion opposite to and substantially parallel to the third bent portion and substantially perpendicular to the first and second bent portions;
a first connecting portion embedded in the plastic portion and connecting the closed sidewall to the first bent portion, the first connecting portion substantially perpendicular to the first bent portion and the closed sidewall;
a second connecting portion embedded in the plastic portion and connecting the closed sidewall to the second bent portion, the second connecting portion substantially perpendicular to the second bent portion and the closed sidewall;
a third connecting portion embedded in the plastic portion and connecting the closed sidewall to the third bent portion, the third connecting portion substantially perpendicular to the third bent portion and the closed sidewall; and
a fourth connecting portion embedded in the plastic portion and connecting the closed sidewall to the fourth bent portion, the fourth connecting portion substantially perpendicular to the fourth bent portion and the closed sidewall.

20. The housing as claimed in claim 19,
wherein, a first space is defined in the support portion substantially along the first bent portion;
wherein, a second space is defined in the support portion substantially along the second bent portion;
wherein, a third space is defined in the support portion substantially along the third bent portion; and
wherein, a fourth space is defined in the support portion substantially along the fourth bent portion.
